(19) United States
(12) Patent Application Publication
(10) Pub. No.: US 2007/0121291 A1
(43) Pub. Date: May 31, 2007

(54) Heat sink module of a notebook computer

(75) Inventors: Frank Wang, Taipei (TW); Chih-Kai Yang, Taipei (TW)

Correspondence Address: LOWE HAUPTMAN BERNER, LLP, 1700 DIAGONAL ROAD, SUITE 300, ALEXANDRIA, VA, 22314, US

(73) Assignee: INVENTEC CORPORATION, Taipei (TW)

(21) Appl. No.: 11/289,707

(22) Filed: Nov. 30, 2005

(51) Int. Cl. H05K 7/20; F28D 15/00

(52) U.S. Cl. 361/695; 361/704; 165/80.3; 165/104.33

(57) ABSTRACT

A heat sink module used in a notebook computer is provided, in which a heat sink fin set is fixed in a fan case and an upper case is disposed on fan leaves within the fan case, the upper cover has a hole disposed at a region over the fan leaves. A heat conducting tube has two ends, with one disposed on the heat sink fin set and the other fixed with a side plate. Then, the thermally conducting piece is fixed on the upper case. Finally, a press and fixation member is disposed on the side plate and assembly of the heat sink module is completed. In case of being used, the thermally conducting piece is bonded on the heat source. As such, not only heat may be moved from the heat source but also the heat sink module has increased strength and reduced weight.

### BACKGROUND OF THE INVENTION

1. Field of the Invention

The present invention relates to a heat sink module. More particularly, the present invention relates to a heat sink module having an increased strength and a reduced weight and capable of efficiently conducting heat generated inside a notebook computer.

2. Description of the Related Art

With development of the electronic technology, transistor numbers in a chip, particularly a central processing unit (CPU), in an electronic device, have increased more and more. Although this may increase data processing speed, the dissipated power and generated heat undesirably increase correspondingly. To enable the CUP to work stably in a computer, the heat sinking problem has to be carefully addressed. For those highly compactness and slightness demanded notebooks, such heat sinking issue is particularly challenging.

For the currently used heat sink modules used in the notebook computers, heat conducting tubes, heat sink elements and a fan are generally utilized as combinations for the heat sink purpose. In principle, the fan is used to cause an air flow which is thermally exchangeable with the heat accumulated at the fin. Since the heat of the fin is moved by the air flow, the temperature reduction of the CPU may be achieved.

However, the required volume of the fans and heat sink elements is placed with an unavoidable demand by the continuously increased transistor numbers in the CPUs, pushed by the rapidly developed CPU technology. Unfortunately, such larger and larger fans and heat sink elements may not be accommodated within the notebook computers of being compactness and slightness demanded.

Now, a disadvantage of the prior art heat sink module will be discussed with reference to FIG. 1. The heat sink module 1″ is composed of a fan and heat sink elements as mentioned above and the fan and heat sink elements are particularly made of copper so as to promote heat sink efficiency. However, another problem is induced since the copper elements are generally accompanied with weight and cost issued. To fix this problem, another prior art heat sink module is set forth, which is schematically shown in FIG. 2. The heat sink module 1′ includes a heat sink element 10′ and a copper piece 20′. On the heat sink element 10′, there is an upper cover 11′ having a hole 12′ thereon. The copper piece 20′ is welded to the hole 12′ on the upper cover 11′ of the heat sink element 10′. Although aluminum is adopted as the heat sink element 10′ in this case and thus the heat sink element 1′ has a reduced weight, this configuration where the copper piece 20′ is welded on the hole 12′, overall strength of the heat sink element 10′ is not sufficient and a connection gap existed between the copper piece 20′ and the hole 12′ may have an adverse effect on the heat sink capability.

As a result, there is a need to redesign a heat sink module having an improved strength and enhanced heat sink efficiency in the notebook computer field.

### SUMMARY OF THE INVENTION

It is, therefore, an object of the present invention to provide a heat sink module used in a notebook computer so as to overcome the weight and strength problems encountered in the prior art.

To achieve the above objects, the heat sink module used in a notebook computer includes a heat sink fin set, a heat conducting tube, a body and a press and fixation member. The body includes a fan case, fan leaves, an upper cover and a thermally conducting piece. The fan case includes a reception space and an opening. A groove is disposed on a first surface of the upper cover of the body. A hole is disposed on a central region of the groove and a side plate is disposed at a side of the hole of the groove so that the heat conducting tube is mated therewith.

In assembling the heat sink module, the heat sink fin set is first mated within the opening of the fan case of the body. Next, the fan leaves are disposed in the reception space of the fan case and the upper cover is disposed on the fan case, the upper cover having a first surface having a hole disposed at a region over the fan leaves. One end of the heat conducting tube is disposed on the reception portion of the heat sink fin set and another end of the heat conducting tube is disposed on the groove of the first surface of the upper cover and is fixed by the side plate. Then, the thermally conducting piece is fixed on a second surface of the upper cover. Finally, the press and fixation member is fixed on the side plate of the first surface of the upper cover. In this manner, the heat sink module is completely assembled. In the case of being used for a heat source of a notebook computer, the thermally conducting piece of the second surface of the upper cover is bonded tightly to the heat source, whereby the heat sinking purpose with respect to the heat source may be well achieved.

In the above, the thermally conducting piece of the thermal heat module is made of copper and the body of the thermal heat module is made of aluminum. With the design, the heat sink module is provided with an enhanced strength and a reduced weight.

In the above, the side plate is shaped approximately like an inverse version of the English letter “L” or the number “1” and disposed at the side of the hole of the groove.

Other and the above objects of the present invention will become more apparent to a person of the skilled art when the following description is read, where implementations of the present invention are discussed in detail in conjunction with the accompanying drawings.

### BRIEF DESCRIPTION OF THE DRAWINGS

The invention will become more fully understood from the detailed description given below for illustration only, and thus are not limitative of the present invention, and wherein:

FIG. 1 shows a schematic diagram of a prior art heat sink module;

FIG. 2 shows a schematic diagram of another prior art heat sink module;

FIG. 3A shows a schematic diagram of a heat sink module thereof according to the present invention;

FIG. 3B an enlarged view of the side plate in FIG. 3A;

FIG. 3C shows a schematic diagram of the heat sink module after assembly and a heat source for which the heat sink module works according to the present invention;

FIG. 3D shows a schematic diagram illustrating the heat sink module is stacked on the heat source according to the present invention;

FIG. 4A shows a schematic diagram of another aspect of the heat sink module according to the present invention; and

FIG. 4B shows an enlarged view of the side plate in FIG. 4A.

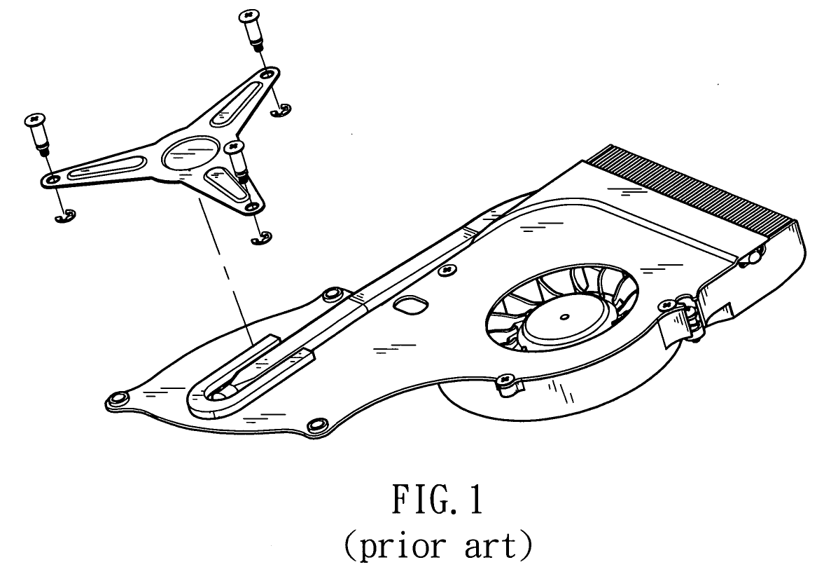

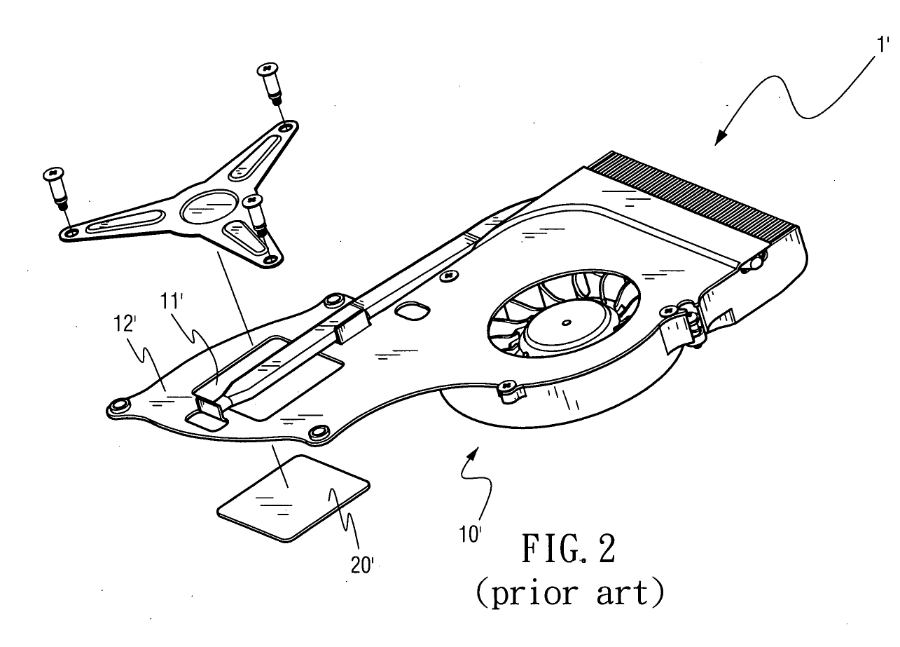

### DETAILED DESCRIPTION OF THE INVENTION

The heat sink module of the present invention will be described in the following in assembly and implementations, with reference to the annexed drawings, and will be particularly described with respect to use in a notebook computer.

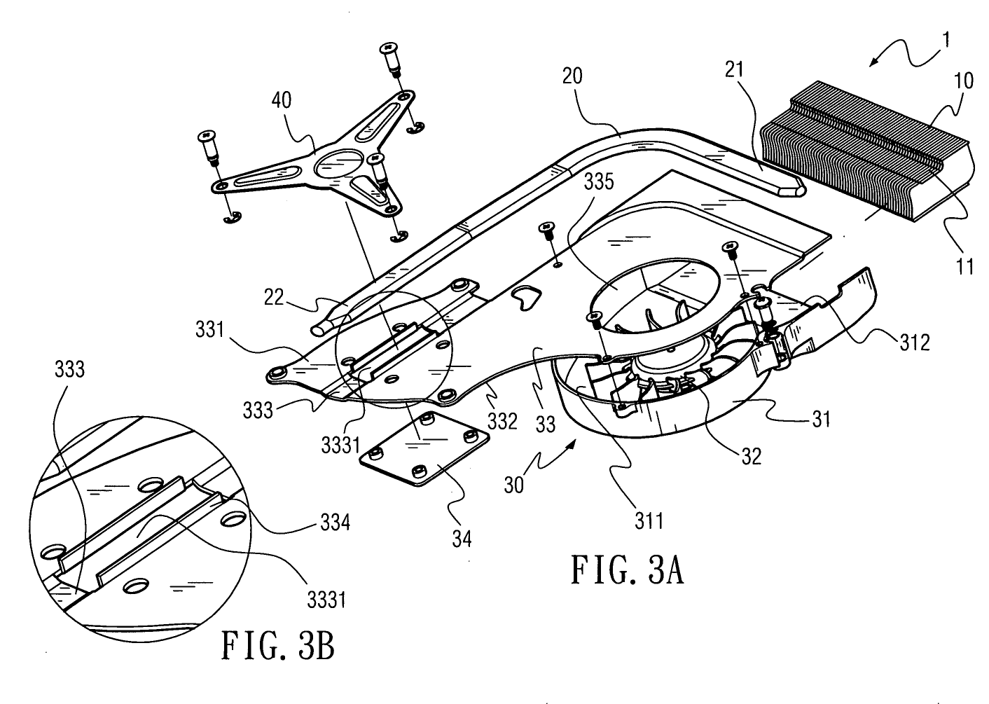

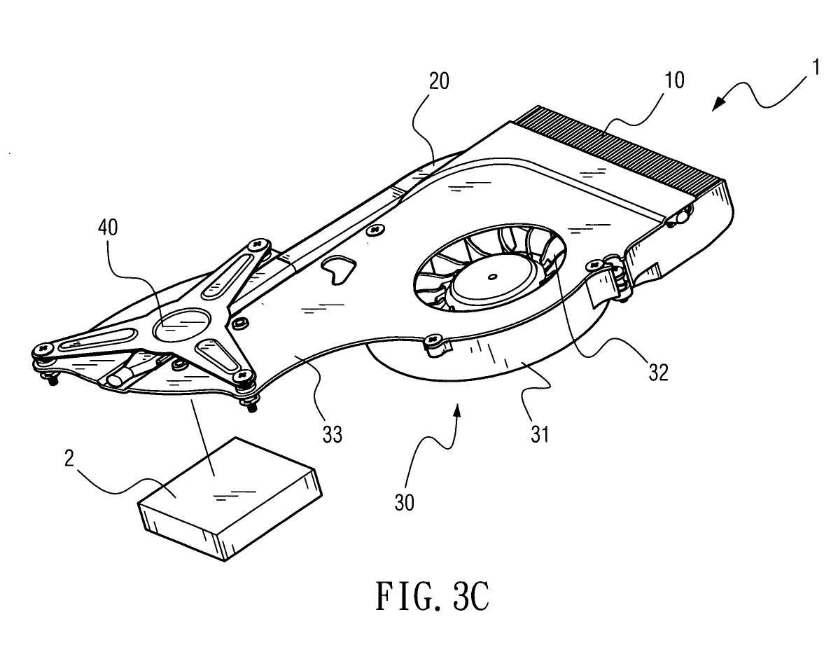

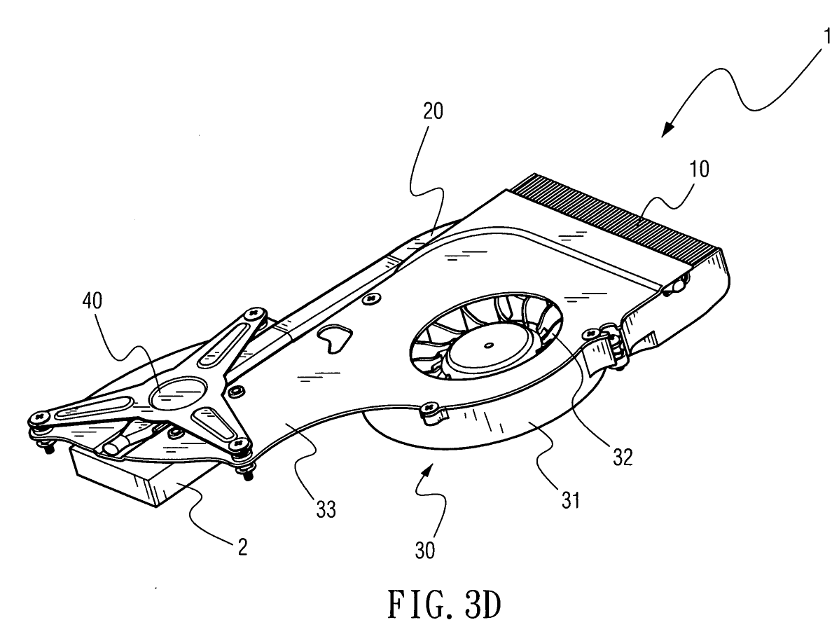

Referring first to FIG. 3A and FIG. 3C, an exploded view and a perspective view of the heat sink module according to the present invention are respectively shown therein. The heat sink module 1 is used to reduce temperature of the notebook when operating. The heat sink module 1 includes a heat sink fin set 10, a heat conducting tube 20, a body 30 and a press and fixation member 40. In the heat sink fin set 10, there is a reception portion 11, which is a bump composed of a plurality of heat sink fins. In the heat conducting tube 20 as shown in FIG. 3A, there is a thermally conducting material contained, which is apparent to those skilled in the art and thus omitted in this specification.

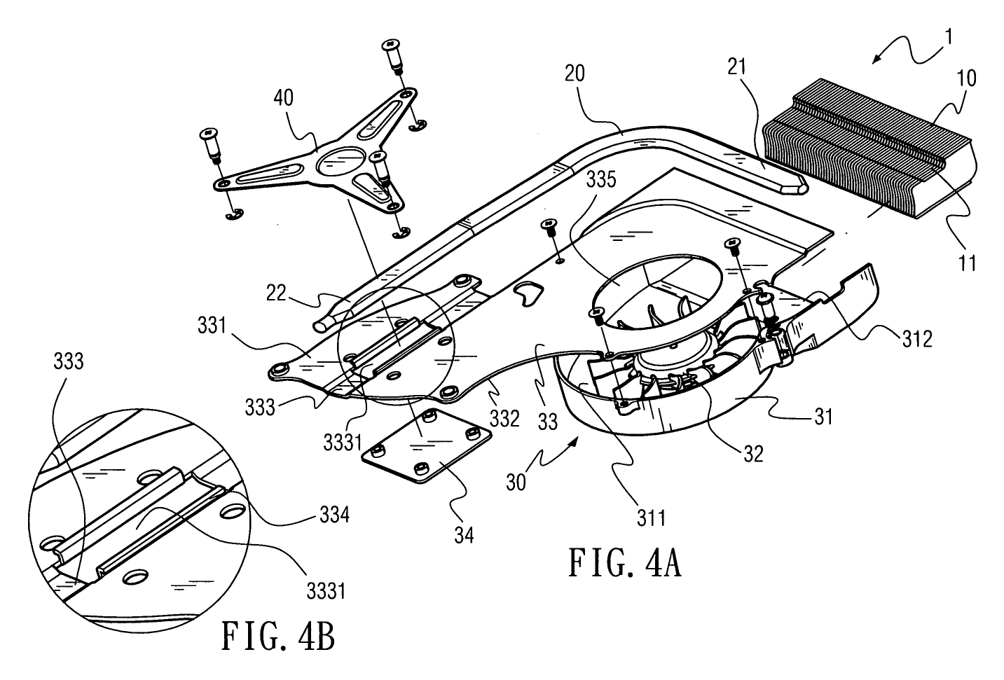

The body 30 includes a fan case 31, fan leaves 32, an upper cover 33 and a thermally conducting piece 34. The fan case 31 is approximately shaped like the English letter “U” and has a reception space 311 and an opening portion 312. The upper cover 33 is approximately shaped like the English letter “d” and has a first surface 331 and second surface 332. On the first surface 331 of the upper cover 33, a groove 333 is disposed. Also, the upper surface of thermally conducting piece 34 and the upper surface of the groove 333 stand at the same level height. On a central region of the groove 333, a hole 3331 is disposed. At a side of the hole 3331, a side plate 334 is disposed so that another end 22 of the heat conducting tube 20 may be mated and fixed and the heat conducting tube 20 may be exempted from being damaged by the press and fixation member 40 when the heat sink module is under an assembly operation as will be described below. The side plate 334 is shaped like an inverse version of the number “1” or the English letter “L” as shown in FIG. 3B and FIG. 4B and disposed at a side of the hole 3331 of the groove 333.

Refer also to FIG. 3A and FIG. 3C. Assembly of the heat sink module of the invention will be described below. First, the heat sink fin set 10 is first mated within the opening portion 312 of the fan case 31 of the body 30. Next, the fan leaves 32 are disposed in the reception space 311 of the fan case 31 and the upper cover 33 is disposed on the fan case 31, the upper cover 33 having a first surface 331 having a hole 335 disposed at a region over the fan leaves 32. One end 21 of the heat conducting tube 20 is disposed on the reception portion 11 of the heat sink fin set 10 and another end 22 is supported on the groove 333 of the first surface 331 of the upper cover 33, respectively. Specifically, the another end 22 is fixed by a side plate 334 at a side of the hole 3331 of the groove 333 and then the thermally conducting piece 34 is fixed on a second surface 332 of the upper cover 33. Finally, the press and fixation member 40 is fixed on the first surface 331 of the upper cover 33 and the side plate 334 of the groove 333 on the first surface 331 of the upper cover 33. In this manner, the heat sink module is completely assembled. In the case of being used for a heat source of a notebook computer, the thermally conducting piece of the second surface of the upper cover is bonded tightly to the heat source, whereby the heat sinking purpose with respect to the heat source may be well achieved.

Referring to FIG. 3A, FIG. 3C and FIG. 3D, an application in which the heat sink module of the invention is bonded on a heat source (particularly a central processing unit (CPU)) 2 of a notebook computer will be illustrated with reference thereto. The heat sink module 1 is bonded tightly onto the heat source 2 at the upper cover 33 of the body 30. Specifically, the heat source 2 is bonded tightly with the thermally conducting piece 34 on the second surface 332 of the upper cover 33. In this case, heat generated from the heat source 2 is absorbed by the thermally conducting piece 34 conducted to the upper cover 33 of the body 30 and the another end 22 of the heat conducting tube 20. Then, the heat is conducted through the upper cover 33 and the heat conducting tube 20 to the end 21 of the heat conducting tube 20 and the heat sink fin set 10. Finally, the fan leaves 32 are operated to move efficiently the heat of the heat sink fin set 10 and heat conducting tube 20 outside the notebook computer. Since the heat may be thermally exchanged with the air outside the notebook computer, the heat generated inside the notebook computer may be efficiently moved with the aid of the operating fan leaves.

In the above, the thermally conducting piece of the thermal heat module is made of copper and the body 30 thereof is made of aluminum. With the design, the heat sink module 1 is provided with an enhanced strength and a reduced weight. Further, the cost required for the heat sink module is reduced, compared with that for the prior art heat sink modules.

While embodiments and applications of this invention have been shown and described, it would be apparent to those skilled in the art having the benefit of this disclosure that many more modifications than mentioned above are possible without departing from the inventive concepts herein. The invention, therefore, is not to be restricted except in the spirit of the appended claims and their equivalents.

What is claimed is:

1. A heat sink module used in a notebook computer comprising a heat sink fin set having a reception portion, a heat conducting tube and a body, the reception being used to fix an end of the heat conducting tube thereon and the body further comprising:
a fan case having a reception space and an opening used for fixation of the heat sink fin set;
fan leaves disposed within the reception space of the fan case;
an upper cover disposed on the fan case, having a hole disposed at a region over the fan leaves in the fan case and having a first and second surface, the first surface having a groove disposed thereon for supporting another end of the thermally conducting tube; and
a thermally conducting piece fixed on the second surface of the upper cover.

2. The heat sink module according to claim 1, wherein the thermally conducting piece is made of copper.

3. The heat sink module according to claim 1, wherein the body is made of aluminum.

4. The heat sink module according to claim 1, wherein a central region of the groove of the first surface of the upper cover has a hole disposed thereon.

5. The heat sink module according to claim 4, wherein a side plate is disposed at a side of the hole of the groove for fixation of another end of the thermally conducting tube.

6. The heat sink module according to claim 5, wherein the side plate is shaped like an inverse version of an English letter “L”.

7. The heat sink module according to claim 5, wherein the side plate is shaped like a number “1”.

8. The heat sink module according to claim 1, further comprising a press and fixation member disposed fixedly and pressing on the side plate.

9. The heat sink module according to claim 5, further comprising a press and fixation member disposed fixedly and pressing on the side plate.

10. The heat sink module according to claim 1, wherein the fan case is approximately like an English letter “U”.

11. The heat sink module according to claim 1, wherein the upper cover is approximately like an English letter “d”.

12. The heat sink module according to claim 1, wherein the upper surface of thermally conducting piece and the upper surface of the groove stand at the same level height.
